(19) United States
(12) Patent Application Publication
(10) Pub. No.: US 2024/0030008 A1
(43) Pub. Date: Jan. 25, 2024

(54) PLASMA PROCESSING APPARATUS AND PLASMA PROCESSING METHOD

(71) Applicant: TOKYO ELECTRON LIMITED, Tokyo (JP)

(72) Inventors: Eiki KAMATA, Yamanashi (JP); Taro HAYAKAWA, Yamanashi (JP); Taro IKEDA, Yamanashi (JP)

(21) Appl. No.: 18/353,757

(22) Filed: Jul. 17, 2023

(30) Foreign Application Priority Data
Jul. 21, 2022 (JP) 2022-116593

(51) Int. Cl. H01J 37/32

(52) U.S. Cl. CPC H01J 37/32715; H01J 37/32357; H01J 37/3222; H01J 2237/20214; H01J 2237/20285

(57) ABSTRACT

A plasma processing apparatus disclosed herein includes a stage disposed in a processing container and configured to mount thereon a substrate, a rotary driving mechanism configured to rotatably drive the stage, and a plurality of plasma sources provided on an upper wall of the processing container facing the stage. The plurality of plasma sources are not arranged axially symmetrically with respect to a rotation axis of the stage.

### CROSS-REFERENCE TO RELATED APPLICATIONS

This application claims priority to Japanese Patent Application No. 2022-116593, filed on Jul. 21, 2022, the entire contents of which are incorporated herein by reference.

### TECHNICAL FIELD

The present disclosure relates to a plasma processing apparatus and a plasma processing method.

### BACKGROUND

Conventionally, a plasma processing apparatus that uses microwaves to generate plasma in a processing container has been known. Japanese Laid-open Patent Publication No. 2012-216745 has been proposed technology in which one antenna module radiating microwaves is disposed on a central portion of a ceiling wall of the processing container, and six antenna modules are disposed outside the central portion to surround the antenna module located in the central portion, thus making the distribution of plasma uniform.

### SUMMARY

The present disclosure provides technology that makes plasma density on a substrate uniform, even when a gap between an upper wall and a stage is shortened.

A plasma processing apparatus according to one aspect of the present disclosure includes a stage disposed in a processing container and configured to mount thereon a substrate, a rotary driving mechanism configured to rotatably drive the stag, and a plurality of plasma sources provided on an upper wall of the processing container facing the stage, the plurality of plasma sources being not arranged axially symmetrically with respect to a rotation axis of the stage.

### BRIEF DESCRIPTION OF THE DRAWINGS

FIG. 1 is a cross-sectional view schematically illustrating an example of a plasma processing apparatus according to an embodiment.

FIG. 2 is a diagram illustrating an example of an arrangement of conventional antenna modules.

FIG. 3 is a diagram illustrating an example of an arrangement of antenna modules according to an embodiment.

FIG. 4 is a diagram illustrating an operation of a plasma processing apparatus according to an embodiment.

FIG. 5 is a diagram illustrating an example of the result of obtaining the diffusion of plasma according to an embodiment.

FIG. 6 is a diagram illustrating an example of a relationship between the diffusion of plasma and a gap according to an embodiment.

FIG. 7 is a diagram illustrating an example of the result of calculating the distribution of the plasma density in a radial direction of a mounting table according to an embodiment.

FIG. 8 is a diagram illustrating an example of the result of comparing plasma density distribution of an embodiment and plasma density distribution of the prior art.

FIG. 9 is a diagram illustrating an example of the configuration of a shower head according to an embodiment.

FIG. 10 is a flowchart illustrating an example of a plasma processing flow according to an embodiment.

### DETAILED DESCRIPTION

Hereinafter, a plasma processing apparatus and a plasma processing method according to an embodiment of the present disclosure will be described in detail with reference to the accompanying drawings. Further, the disclosed plasma processing apparatus and plasma processing method are not limited to this embodiment.

In the plasma processing apparatus, it is desired to shorten a gap between an upper wall of a processing container in which an antenna module is arranged and a stage on which a substrate is mounted, in consideration of productivity or energy saving. However, if the gap is shortened in the conventional antenna module arrangement, the plasma is not sufficiently diffused, so that the uniformity of the plasma density on a substrate may not be ensured.

Therefore, there is a need for technology making uniformity of plasma density on a substrate, even when a gap between an upper wall and a mounting table is shortened.

### Embodiment

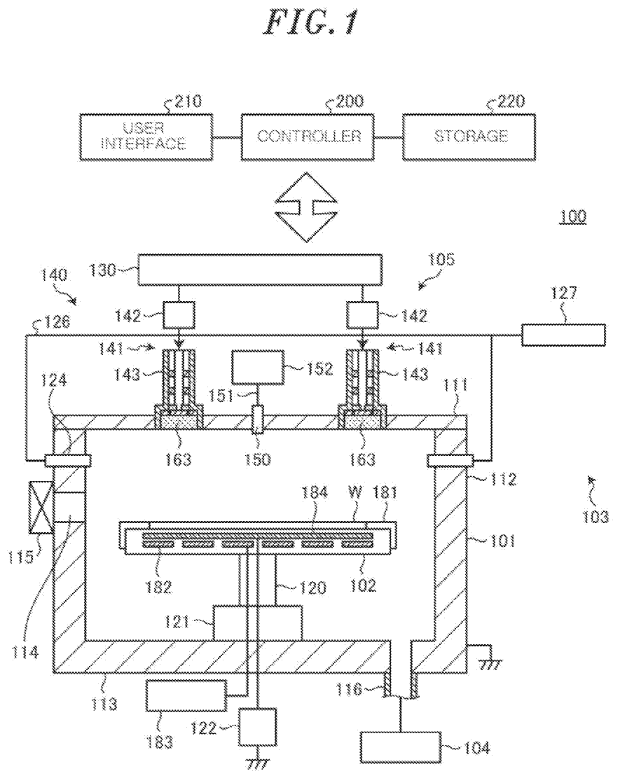

An embodiment will be described. FIG. 1 is a cross-sectional view schematically illustrating an example of a plasma processing apparatus 100 according to an embodiment. The plasma processing apparatus 100 is an apparatus that generates plasma by microwaves. The plasma processing apparatus 100 shown in FIG. 1 includes a processing container 101, a mounting table 102, a gas supply mechanism 103, an exhaust device 104, a microwave introduction device 105, and a controller 200.

The processing container 101 accommodates a substrate W such as a semiconductor wafer. The mounting table 102 is installed in the processing container 101. The substrate W is mounted on the mounting table 102. In this embodiment, the mounting table 102 corresponds to the stage of the present disclosure.

The gas supply mechanism 103 supplies gas into the processing container 101. The exhaust device 104 exhausts the inside of the processing container 101. The microwave introduction device 105 generates microwaves for generating plasma in the processing container 101, and simultaneously introduces the microwaves into the processing container 101. The controller 200 controls the operation of each part of the plasma processing apparatus 100.

The processing container 101 is formed of metal material such as aluminum and an alloy thereof, and has a substantially cylindrical shape. The processing container 101 has a plate-shaped ceiling wall 111, a bottom wall 113, and a sidewall 112 connecting the ceiling wall and the bottom wall. The inner wall of the processing container 101 is coated with a protective film such as yttria (Y₂O₃).

The microwave introduction device 105 is installed above the processing container 101, and introduces electromagnetic waves (microwaves) into the processing container 101 to generate plasma. The microwave introduction device 105 will be described below in detail.

The ceiling wall 111 has a plurality of openings into which microwave radiation mechanisms 143 of the microwave introduction device 105, which will be described later, are fitted. The sidewall 112 has a loading/unloading port 114 for loading and unloading the substrate W into and from a transfer chamber (not shown) that is adjacent to the processing container 101. Further, the sidewall 112 is provided with a gas introduction nozzle 124 at a position above the mounting table 102. The loading/unloading port 114 is configured to be opened or closed by a gate valve 115.

The bottom wall 113 is provided with an opening, and an exhaust device 104 is installed via an exhaust pipe 116 connected to the opening. The exhaust device 104 is provided with a vacuum pump and a pressure control valve. The inside of the processing container 101 is evacuated via the exhaust pipe 116 by the vacuum pump of the exhaust device 104. A pressure in the processing container 101 is controlled by the pressure control valve of the exhaust device 104.

The mounting table 102 is formed in a disk shape. For example, the mounting table 102 is formed of aluminum having an anodized surface, or a ceramic material, such as aluminum nitride (AlN). The substrate W is mounted on the upper surface of the mounting table 102. The mounting table 102 is supported by a support member 120 formed of ceramics, such as cylindrical AlN, on the central portion of the bottom thereof. A rotary driving mechanism 121 is provided on the central portion of the bottom of the processing container 101. The rotary driving mechanism 121 rotatably supports the support member 120. The mounting table 102 is rotatably supported by the support member 120 and the rotary driving mechanism 121. The rotary driving mechanism 121 has a motor installed therein, and rotates the mounting table 102 by rotating the support member 120 with the driving force of the motor. The mounting table 102 rotates in a circumferential direction with a disk-shaped central axis as a rotation axis. A guide ring 181 for guiding the substrate W is provided on an outer edge of the mounting table 102. Further, a lifting pin (not shown) is installed inside of the mounting table 102 to move the substrate W up and down, protruding from and retracting into the upper surface of the mounting table 102.

A resistance heating type heater 182 is embedded in the mounting table 102. Further, an electrode 184 having the same size as the substrate W is embedded in the mounting table 102 above the heater 182. In addition, a thermocouple (not shown) is inserted into the mounting table 102. The heater 182, the electrode 184, and the thermocouple of the support member 120 are electrically connected to the rotary driving mechanism 121. For example, the rotary driving mechanism 121 is provided with a slip ring, and is electrically connected to wires connected to the heater 182, the electrode 184, and the thermocouple via the slip ring. The heater 182 is connected to a heater power source 183 via the rotary driving mechanism 121. The electrode 184 is connected to a DC power supply 122 via the rotary driving mechanism 121. The thermocouple is connected to the controller 200 via the rotary driving mechanism 121. The heater 182 is supplied with power from the heater power source 183 to heat the substrate W mounted on the mounting table 102. Further, the mounting table 102 may control the heating temperature of the substrate W in response to a signal from the thermocouple. The DC power supply 122 periodically applies a DC voltage to the electrode 184 in the mounting table 102. For example, the DC power supply 122 includes a DC power supply and a pulse unit. The DC power supply 122 turns on or off the DC voltage supplied from the DC power supply by the pulse unit to periodically apply the pulsed DC voltage to the electrode 184.

The gas supply mechanism 103 supplies various gases into the processing container 101. The gas supply mechanism 103 has a gas introduction nozzle 124, a gas supply pipe 126, and a gas supply 127. The gas introduction nozzle 124 is fitted into the opening formed in the sidewall 112 of the processing container 101. The gas supply 127 is connected to each gas introduction nozzle 124 via the gas supply pipe 126. Further, the gas supply 127 has a source of various gases. Further, the gas supply 127 includes an opening and closing valve for starting and stopping the supply of various gases or a flow rate adjustment part for adjusting the flow rate of gas. The gas supply 127 supplies various gases such as processing gas used for plasma processing.

The microwave introduction device 105 is provided above the processing container 101. The microwave introduction device 105 introduces electromagnetic waves (microwaves) into the processing container 101 to generate plasma.

The microwave introduction device 105 has a microwave output part 130 and an antenna unit 140. The microwave output part 130 simultaneously generates microwaves and distributes the microwaves through multiple paths for output. The antenna unit 140 introduces the microwaves, which are output from the microwave output part 130, into the processing container 101.

The microwave output part 130 has a microwave power source, a microwave oscillator, an amplifier, and a distributor. The microwave oscillator is a solid state, and oscillates microwaves (e.g., PLL oscillation) at 860 MHz, for example. The frequency of the microwaves is not limited to 860 MHz, and frequencies in the range of 700 MHz to 10 GHz, such as 2.45 GHz, 8.35 GHz, 5.8 GHz, or 1.98 GHz may be used. The amplifier amplifies the microwaves oscillated by the microwave oscillator. The distributor distributes the microwaves amplified by the amplifier into the plurality of paths. The distributor distributes the microwaves while matching impedance of an input side with impedance of an output side.

The antenna unit 140 has a plurality of antenna modules 141. In FIG. 1, two antenna modules 141 of the antenna unit 140 are shown. In this embodiment, the antenna module 141 configured to supply electromagnetic waves (microwaves) into the processing container 101 corresponds to a plasma source of the present disclosure.

The plurality of antenna modules 141 are not arranged to form axial symmetry with respect to the rotation axis about which the mounting table 102 rotates, but are arranged asymmetrically with respect to the rotation axis of the mounting table 102. Each antenna module 141 has an amplifier 142 and a microwave radiation mechanism 143. The microwave output part 130 simultaneously generates microwaves, distributes the microwaves, and outputs the microwaves to each antenna module 141. The amplifier 142 of the antenna module 141 mainly amplifies the distributed microwaves and outputs the microwaves to the microwave radiation mechanism 143. The microwave radiation mechanism 143 is provided in the ceiling wall 111. The microwave radiation mechanism 143 radiates the microwaves output from the amplifier 142 into the processing container 101. In this embodiment, the ceiling wall 111 corresponds to the upper wall of the processing container 101 of the present disclosure.

The amplifier 142 has a phase shifter, a variable gain amplifier, a main amplifier, and an isolator. The phase shifter changes the phase of microwaves. The variable gain amplifier adjusts the power level of the microwaves that are input into the main amplifier. The main amplifier is configured as a solid state amplifier. The isolator isolates reflected microwaves which are reflected from the antenna part of the microwave radiation mechanism 143 to be described later and are directed towards the main amplifier.

As shown in FIG. 1, the plurality of microwave radiation mechanisms 143 are installed in the ceiling wall 111. Further, the microwave radiation mechanism 143 has a cylindrical outer conductor, and an inner conductor provided in the outer conductor to be coaxial with the outer conductor. Further, the microwave radiation mechanism 143 has a coaxial tube that has a microwave transmission path between the outer conductor and the inner conductor, and an antenna part that radiates the microwaves into the processing container 101. A microwave transmitting plate 163 fitted into the ceiling wall 111 is provided on the lower surface of the antenna part. The lower surface of the microwave transmitting plate 163 is exposed to the inner space of the processing container 101. The microwaves transmitted through the microwave transmitting plate 163 generate plasma in the space of the processing container 101. Further, a position where the microwave transmitting plate 163 is provided may be considered as a position where the plasma source is disposed.

The antenna unit 140 controls the amplifier 142 of each antenna module 141 to adjust the power of microwaves radiated from the microwave radiation mechanism 143 of each antenna module 141.

An introduction part 150 for introducing remote plasma is provided on the ceiling wall 111. The introduction part 150 is provided at a position corresponding to the rotation axis of the mounting table 102. For example, the introduction part 150 is provided on the rotation axis of the mounting table 102. A remote plasma unit 152 is connected to the introduction part 150 via a pipe 151. The remote plasma unit 152 generates the remote plasma of cleaning gas and supplies it to the pipe 151 during cleaning. Examples of the cleaning gas may include NF₃ gas. The plasma-activated cleaning gas is introduced from the introduction part 150 into the processing container 101 through the pipe 151.

The operation of the plasma processing apparatus 100 configured as described above is controlled integrally by the controller 200. A user interface 210 and a storage 220 are connected to the controller 200.

The user interface 210 includes an operation part, such as a keyboard, through which a process manager inputs a command to manage the plasma processing apparatus 100, or a display part, such as a display, which visualizes and displays the operation status of the plasma processing apparatus 100. The user interface 210 receives various operations. For instance, the user interface 210 receives a predetermined operation instructing the start of plasma processing.

The storage 220 is a storage device that stores various pieces of data. For example, the storage 220 is a storage device such as a hard disk, a Solid State Drive (SSD), or an optical disk. Further, the storage 220 may be a semiconductor memory capable of recording data, such as a Random Access Memory (RAM), a flash memory, or a Non Volatile Static Random Access Memory (NVSRAM).

The storage 220 stores an Operating System (OS) executed by the controller 200 or various recipes. For example, the storage 220 stores various recipes including a recipe that executes the plasma processing or a recipe that executes cleaning in the processing container 101. Further, the storage 220 stores various pieces of data used in the recipe. Further, the program or data may be contained in a computer recording medium (e.g., hard disk, CD, flexible disk, semiconductor memory, etc.) that is readable by a computer. Alternatively, the program or data may be transmitted from another device, for example, via a dedicated line at any time and then be used online.

The controller 200 is a device that controls the plasma processing apparatus 100. The controller 200 may employ an electronic circuit such as a Central Processing Unit (CPU) or a Micro Processing Unit (MPU) or an integrated circuit such as an Application Specific Integrated Circuit (ASIC) or a Field Programmable Gate Array (FPGA). The controller 200 has an internal memory for containing a program defining various process sequences or control data, and executes various processes using them.

The controller 200 controls each part of the plasma processing apparatus 100. For example, the controller 200 controls each part of the plasma processing apparatus 100 to perform plasma processing or cleaning according to the recipe of the recipe data stored in the storage 220. For example, the plasma processing apparatus 100 performs plasma processing on the substrate W that is mounted on the mounting table 102. The plasma processing apparatus 100 generates plasma by the microwaves in the processing container 101.

In the conventional plasma processing apparatus, a plurality of plasma sources are symmetrically arranged with respect to the center of the stage, which is the center of the substrate, to make uniform plasma density on the substrate. As a comparative example, an example of the arrangement of the conventional plasma sources will be described. For example, in the plasma processing apparatus of Japanese Laid-open Patent Publication No. 2012-216745, one antenna module is arranged on the central portion of the ceiling wall of the processing container, and six antenna modules are arranged outside the central portion so as to surround the antenna module of the central portion.

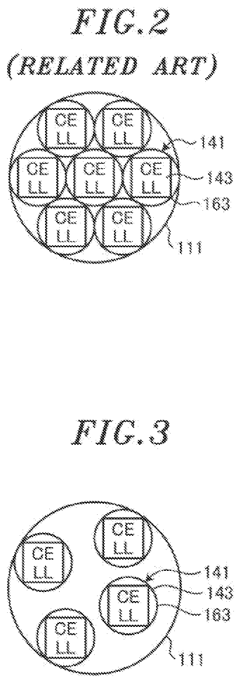

FIG. 2 is a diagram illustrating an example of the arrangement of the conventional antenna modules 141. Seven antenna modules 141 are provided on the ceiling wall 111. In FIG. 2, the microwave radiation mechanism 143 of the antenna module 141 is denoted by “CELL”. Six microwave radiation mechanisms 143 are arranged at the vertices of a regular hexagon, and one microwave radiation mechanism is arranged at the center of the regular hexagon. Further, the microwave transmitting plates 163 are disposed on the ceiling wall 111 to correspond to the seven microwave radiation mechanisms 143, respectively. These seven microwave transmitting plates 163 are arranged such that neighboring microwave transmitting plates 163 are equidistantly spaced.

As described above, the plasma processing apparatus 100 requires shortened gap between the ceiling wall 111 and the mounting table 102 to enhance productivity or energy efficiency. From the viewpoint of cost reduction, it is also required to reduce the number of antenna modules 141. However, if the gap is shortened with the conventional arrangement of the antenna modules 141, the arrangement of the antenna modules 141 is transferred, thus making it impossible to secure the uniformity of plasma on the substrate W. For example, in FIG. 2, the arrangement of the seven antenna modules 141 is transferred to the substrate W.

Therefore, the plasma processing apparatus 100 according to an embodiment is configured to rotate the mounting table 102 by rotating the support member 120 by the rotary driving mechanism 121. Further, the plasma processing apparatus 100 according to an embodiment is configured such that the plurality of antenna modules 141 on the ceiling wall 111 are not arranged to be symmetrical with respect to the rotation axis about which the mounting table 102 rotates, but are arranged to be asymmetrical with respect to the rotation axis of the mounting table 102. FIG. 3 is a diagram illustrating an example of the arrangement of the antenna modules 141 according to an embodiment. Four antenna modules 141 are provided on the ceiling wall 111. In FIG. 3, the microwave radiation mechanism 143 of the antenna module 141 is denoted by “CELL.” The plurality of antenna modules 141 are arranged on the ceiling wall 111 such that the plasma density distribution in the radial direction of the mounting table 102 is within a predetermined range when each antenna module generates plasma with a predetermined power. The predetermined range is determined according to conditions required for plasma processing.

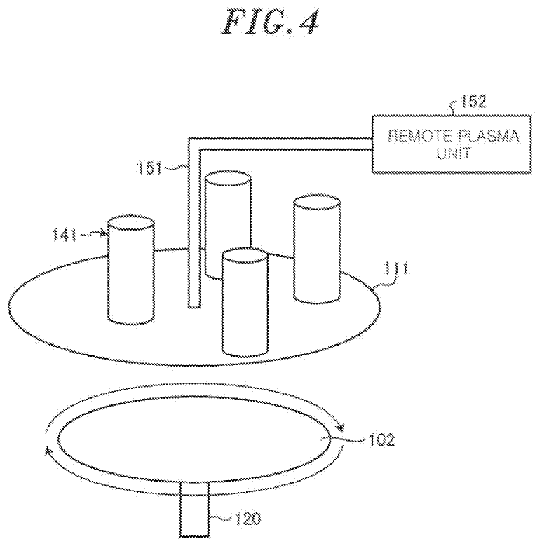

FIG. 4 is a diagram illustrating the operation of the plasma processing apparatus 100 according to an embodiment. The plasma processing apparatus 100 according to an embodiment introduces microwaves from each antenna module 141 to generate plasma by microwaves in the processing container 101 while rotating the mounting table 102. For example, the controller 200 rotatably drives the mounting table 102 by the rotary driving mechanism 121 when plasma processing on the substrate W is performed. The controller 200 controls the gas supply 127 and the microwave introduction device 105, and introduces the microwaves from each antenna module 141 into the processing container 101 to generate plasma while supplying the processing gas used for plasma processing from the gas supply 127 into the processing container 101.

Since the plasma processing apparatus 100 according to an embodiment is configured such that the mounting table 102 is rotatable by the rotary driving mechanism 121, it is possible to make a uniform plasma density on the substrate W even if the antenna module 141 is not disposed to be axially symmetrical with respect to the rotation axis of the mounting table 102. Further, the plasma processing apparatus 100 according to an embodiment can reduce the number of the antenna modules 141, thus realizing cost saving. Further, the plasma processing apparatus 100 according to an embodiment can maintain a uniform plasma density on the substrate even if the number of the antenna modules 141 is reduced compared to the prior art.

However, in the conventional apparatus, it was necessary to dispose the antenna module 141 on the center so as to secure the uniformity of the plasma density. For this reason, in the conventional apparatus, even when it is desired to clean the inside of the processing container 101 with remote plasma that is milder than direct plasma, it is impossible to introduce the remote plasma from the center, so that the inside of the processing container 101 cannot be uniformly cleaned.

In contrast, the plasma processing apparatus 100 according to an embodiment does not need to dispose the antenna module 141 on the center of the ceiling wall 111. The plasma processing apparatus 100 according to an embodiment includes the introduction part 150 for introducing the remote plasma around the center of the ceiling wall 111. The introduction part 150 is provided on a location corresponding to the rotation axis of the mounting table 102. During cleaning, the plasma processing apparatus 100 generates the remote plasma of cleaning gas by the remote plasma unit 152, and introduces the plasma-activated cleaning gas from the introduction part 150 into the processing container 101 via the pipe 151. As such, the plasma processing apparatus 100 according to an embodiment can uniformly clean the inside of the processing container 101, by introducing the plasma-activated cleaning gas by the remote plasma from near the center of the ceiling wall 111 into the processing container 101.

Next, the arrangement of the antenna module 141 in the plasma processing apparatus 100 according to an embodiment will be described. The antenna module 141 generates plasma by the microwaves. The density of the plasma generated by the microwaves decreases as a distance from the antenna module 141 increases. FIG. 5 is a diagram illustrating an example of the result of obtaining the diffusion of plasma according to an embodiment. FIG. 5 shows the distribution of the plasma density when the microwaves are radiated and generated from one antenna module 141. When the position on the mounting table 102 directly below the center of the microwave transmitting plate 163 is set as a reference point, the horizontal axis of FIG. 5 represents a distance on the mounting table 102 from the reference point. The vertical axis represents the plasma density. The plasma density is a normalized value. A line L11 is the result of measuring the plasma density at a distance r from the reference point on the mounting table 102. The line L11 may be approximated by the following Equation (1). By fitting, the value of parameter a in Equation (1) is determined. A line L12 is a line obtained from Equation (1) to which the value of parameter a determined by fitting is applied.

$$d = {e}^{- \frac{{r}^{2}}{{a}^{2}}} \qquad ( 1 )$$

Here,
d is the plasma density.
r is the distance on the mounting table 102.
a is the parameter.

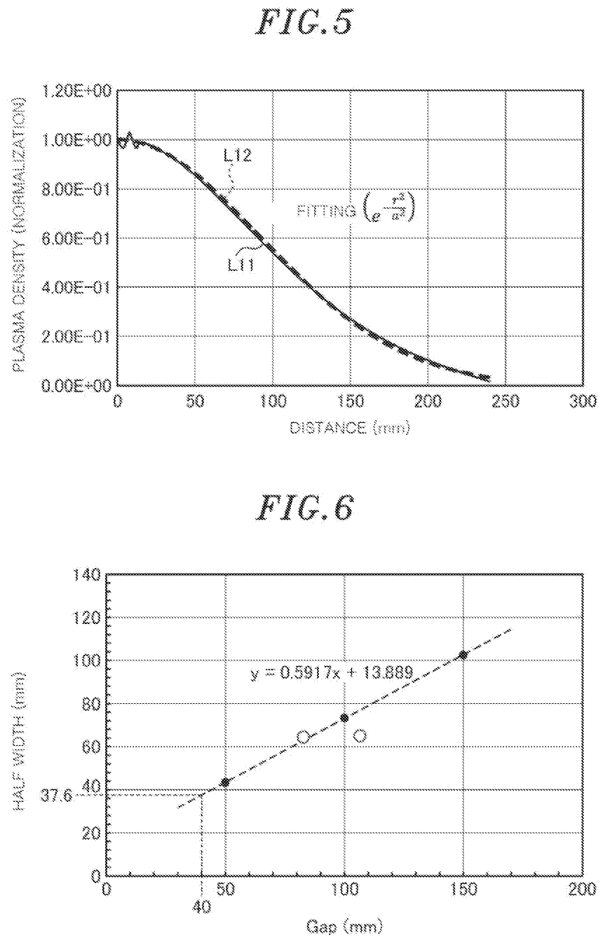

FIG. 6 is a diagram illustrating an example of a relationship between the diffusion of plasma and the gap according to an embodiment. FIG. 6 shows the relationship between the distance (Gap) between the ceiling wall 111 on which the antenna module 141 is provided and the mounting table 102 and a half width at which the plasma density distribution is halved. The horizontal axis of FIG. 6 is the distance (Gap) between the ceiling wall 111 on which the antenna module 141 is provided and the mounting table 102. The vertical axis is the half width at which the plasma density distribution is halved. FIG. 6 shows an approximate straight line that approximates the relationship between x and y, where x is the distance (Gap) and y is the half width, and an equation for the approximate straight line. As shown in FIG. 6, as the gap between the ceiling wall 111 and the mounting table 102 decreases, the half width of the plasma density decreases. For example, when the gap is 40 mm, the half width is 37.6 mm. Therefore, if the gap between the ceiling wall 111 and the mounting table 102 is shortened, the plasma generated by each antenna module 141 is not sufficiently diffused, so that the uniformity of the plasma density on the substrate W cannot be ensured.

On the other hand, the plasma processing apparatus 100 according to an embodiment is configured to rotate the mounting table 102, so that it is possible to make the plasma density on the substrate W uniform, even if each antenna module 141 is arranged asymmetrically with respect to the rotation axis of the mounting table 102 and the number of the antenna modules 141 is reduced compared to the prior art.

An example of the arrangement of the antenna modules 141 according to an embodiment will be described. When the substrate is processed, the substrate W rotates as the mounting table 102 rotates. For each antenna module 141, the position in the radial direction of the mounting table 102 and the power to radiate the microwaves may be determined so as to ensure the uniformity of the plasma density in the radial direction of the mounting table 102.

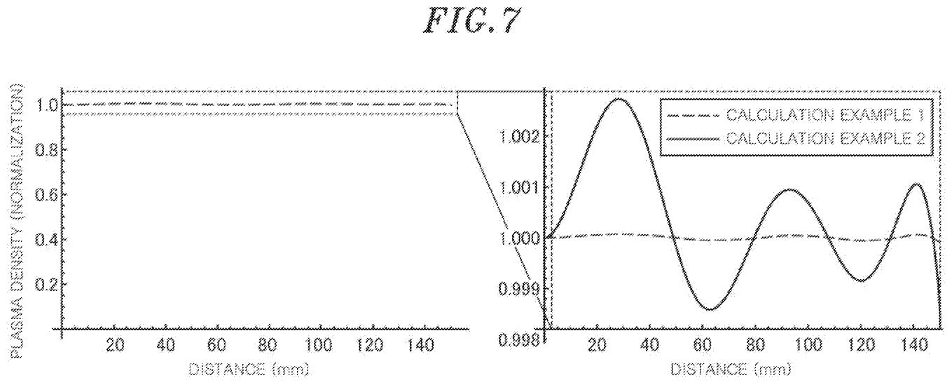

FIG. 7 is a diagram illustrating an example of the result of calculating the distribution of the plasma density in the radial direction of the mounting table 102 according to an embodiment. The horizontal axis of FIG. 7 represents a distance from the center of the mounting table 102 in the radial direction. The vertical axis represents the plasma density. The plasma density is a normalized value. The left side of FIG. 7 shows a graph representing the entire distribution of the plasma density in the radial direction of the mounting table 102. The right side of FIG. 7 shows an enlarged view of a graph for the plasma density of about 0.998 to 1.003.

It is assumed that each antenna module 141 is arranged at a distance r within the range of 0≤r≤220 from the center of the mounting table 102. For each antenna module 141, the distance from the center of the mounting table 102 is ri, and the microwave radiation power is pi. i is a number sequentially assigned from 1 for each antenna module 141 from a side near the center of the mounting table 102. The power P for radiating microwaves is such that the power P1 of the innermost antenna module 141 with number i=1 is 1 (P1=1), and the power Pi of each antenna module 141 with number i≤2 is 0.5 or more and 2 or less (0.5≤Pi≤2).

First, as calculation example 1, an example in which the gap between the ceiling wall 111 and the mounting table 102 is set to 80 mm and seven antenna modules 141 are arranged to calculate the plasma density distribution will be described. When the gap is 80 mm, the half width of the plasma density is 61.2 mm. The arrangement positions of seven (i=1 to 7) antenna modules 141 are r1=53.2, r2=111, r3=136, r4=162, r5=220, r6=220, and r7=220. Further, the power P with which the seven (i=1 to 7) antenna modules 141 radiating microwaves is assumed to be p1=1, p2=0.952, p3=1.60, p4=0.835, p5=1.79, p6=1.81 and p7=1.82. In FIG. 7, the plasma density distribution of calculation example 1 is shown by a dashed line. Calculation example 1 may uniformize the plasma density to approximately 1.000.

Next, as calculation example 2, an example in which the gap between the ceiling wall 111 and the mounting table 102 is set to 40 mm and seven antenna modules 141 are arranged to calculate the plasma density distribution will be described. When the gap is 40 mm, the half width of the plasma density is 37.6 mm. The arrangement positions of seven (i=1 to 7) antenna modules 141 are r1=36.6, r2=81.4, r3=118, r4=140, r5=171, r6=186, and r7=186. Further, the power P with which four (i=1 to 7) antenna modules 141 radiating microwaves is assumed to be p1=1, p2=p3=p4=p5=p6=p7=2.0. In FIG. 7, the plasma density distribution of calculation example 2 is shown by a solid line. Compared to calculation example 1, calculation example 2 is undulating but is within the range of 1.003 to 0.998, and can sufficiently uniformize the plasma density.

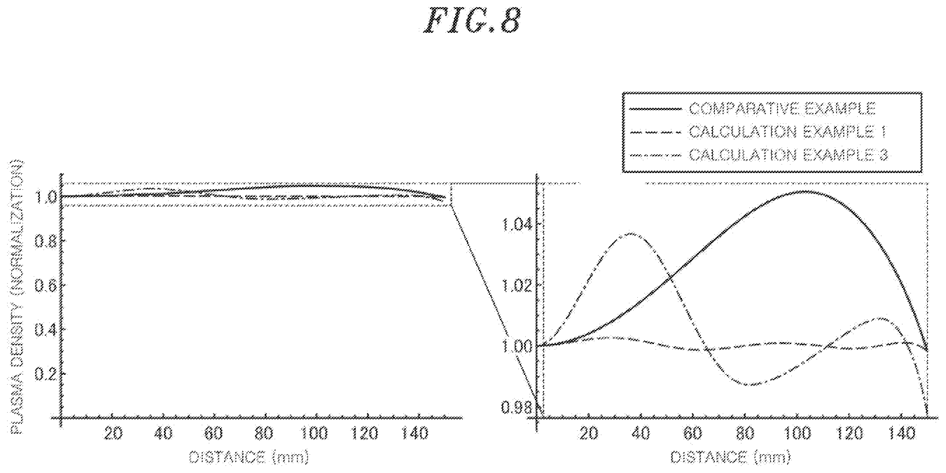

FIG. 8 is a diagram illustrating an example of the result of comparing the plasma density distribution of an embodiment and the plasma density distribution of the prior art. The horizontal axis of FIG. 8 represents a distance from the center of the mounting table 102 in the radial direction. The vertical axis represents the plasma density. The plasma density is a normalized value. The left side of FIG. 8 shows a graph representing the entire distribution of the plasma density in the radial direction of the mounting table 102. The right side of FIG. 8 shows an enlarged view of a graph for the plasma density of about 0.98 to 1.04.

FIG. 8 shows the plasma density distribution of calculation example 1 described above. Further, FIG. 8 shows the plasma density distribution of calculation example 3. In calculation example 3, when the gap between the ceiling wall 111 and the mounting table 102 is set to 40 mm and four antenna modules 141 are arranged, the plasma density distribution is calculated. The arrangement positions of four (i=1 to 4) antenna modules 141 are r1=45.3, r2=102, r3=151, and r4=170. Further, the power P with which the four (i=1 to 4) antenna modules 141 radiate microwaves is set to be p1=1, p2=p3=p4=2.0. In addition, FIG. 8 shows the plasma density distribution of a comparative example. As shown in FIG. 2, the comparative example is a case in which seven antenna modules 141 are arranged at the vertices of a regular hexagon and the center of the regular hexagon. In the comparative example, only power P with which seven antenna modules 141 radiate microwaves is optimized. As shown in FIG. 8, calculation examples 1 and 3 make the plasma density more uniform compared to the comparative example. For example, in calculation example 3, even when the number of antenna modules 141 is reduced to four, the plasma density becomes sufficiently uniform.

Further, in the plasma processing apparatus 100 according to the embodiment, the number of antenna modules 141 arranged on the ceiling wall 111 is not limited to four or seven. Any number is possible as long as the number of antenna modules 141 is seven or less. Further, the arrangement position of each antenna module 141 and the power P for radiating microwaves are only an example, and the present disclosure is not limited thereto. The arrangement position and power P may be determined so that the plasma density distribution is within a predetermined range to be filled by plasma processing.

When the arrangement position and the power P are optimized to make the plasma density uniform in this way, each antenna module 141 is arranged asymmetrically with respect to the rotation axis of the mounting table 102 instead of being axially symmetrical with respect to the rotation axis of the mounting table 102. Further, the antenna modules 141 are arranged such that the arrangement density in the radial direction of the mounting table 102 increases toward the outside. That is, the antenna modules 141 are arranged at shorter intervals in the radial direction toward the radially outside of the mounting table 102.

If the antenna modules 141 are biased on a side of the ceiling wall 111, the balance of weight becomes poor. In addition, when the antenna modules 141 are biased on a side of the ceiling wall 111, a surrounding space becomes narrower, so that it is difficult to handle wiring or the like, and interference with other members may occur. For this reason, it is preferable that the antenna modules 141 are arranged on the ceiling wall 111 so as to be separated from each other. For example, the antenna modules 141 are preferably arranged such that inner and outer antenna modules 141 in the radial direction of the mounting table 102 appear alternately with respect to the rotation direction of the mounting table 102.

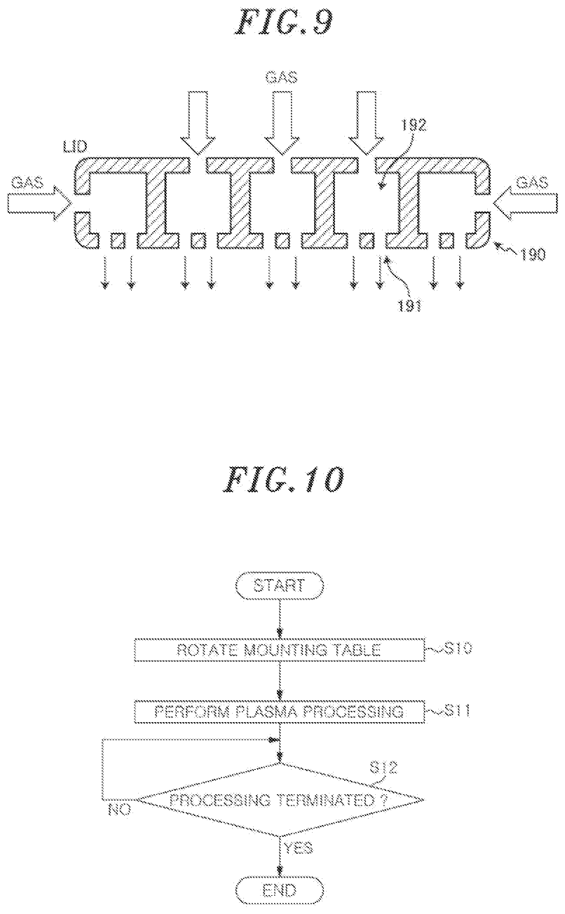

The plasma processing apparatus 100 according to an embodiment is configured to rotate the mounting table 102, so that the plasma density on the substrate W can be sufficiently uniform even when the number of antenna modules 141 arranged on the ceiling wall 111 is reduced. Further, the plasma processing apparatus 100 may arrange the antenna modules 141 on the ceiling wall 111 asymmetrically with respect to the rotation axis of the mounting table 102. As shown in FIG. 3, the ceiling wall 111 has a reduced number of antenna modules 141, so that a proportion occupied by the area of the microwave transmitting plate 163 is reduced. Further, the ceiling wall 111 does not need to arrange the microwave transmitting plate 163 near the center. Therefore, the plasma processing apparatus 100 according to an embodiment may be provided with a shower head for ejecting gas on the ceiling wall 111 where the antenna module 141 is not arranged. FIG. 9 is a diagram illustrating an example of the configuration of the shower head according to an embodiment. FIG. 9 shows an example of the configuration of the shower head 190. The shower head 190 is provided in a portion of the ceiling wall 111 on the inner surface of the processing container 101 where the antenna module 141 is not arranged. An ejection port 191 is formed on a lower surface of the shower head 190 to eject gas. Thereby, the plasma processing apparatus 100 according to an embodiment may supply gas from an upper surface to the entire substrate W.

The shower head 190 may be configured to adjust the type and ejection amount of gas for each area. For example, the shower head 190 forms a plurality of partitioned spaces 192 inside each area. The ejection port 191 communicates with any one space 192. Each space 192 is connected to the gas supply 127 via a pipe (not shown). The gas supply 127 supplies various gases, such as processing gas used for plasma processing, via the pipe to each space 192. The ejection port 191 ejects supplied gas to the communicating space 192. Thereby, the plasma processing apparatus 100 according to an embodiment may adjust the type and ejection amount of gas supplied from the upper surface for each area. Further, by providing the space 192 in the ceiling wall 111, the shower head 190 may be integrated with the ceiling wall 111.

[Plasma Processing Method]

Next, a plasma processing flow using a plasma processing method according to an embodiment will be described. FIG. 10 is a flowchart illustrating an example of the plasma processing flow according to an embodiment. When plasma processing is performed in the plasma processing apparatus 100, the substrate W to be subjected to plasma processing is mounted on the mounting table 102.

The plasma processing apparatus 100 rotates the mounting table 102 (step S10). For example, the controller 200 rotatably drives the mounting table 102 by the rotary driving mechanism 121.

The plasma processing apparatus 100 supplies processing gas into the processing container 101, generates plasma in the processing container 101, and performs plasma processing on the substrate W (step S11). For example, the controller 200 controls the gas supply 127 and the microwave introduction device 105 to supply the processing gas from the gas supply 127 into the processing container 101 and introduce the microwaves from each antenna module 141 into the processing container 101, thus generating the plasma.

The plasma processing apparatus 100 determines whether or not to terminate the processing (step S12). For example, the controller 200 determines whether a predetermined processing time has elapsed since the start of plasma processing, and terminates processing when the predetermined processing time has elapsed (step S12: Yes). On the other hand, when the predetermined processing time has not elapsed (step S12: No), the process proceeds to step S10 to continue the process.

As described above, the plasma processing apparatus 100 according to an embodiment has the mounting table (stage) 102, the rotary driving mechanism 121, and the plurality of antenna units 140 (plasma sources). The mounting table 102 is disposed in the processing container 101, and the substrate W is mounted on the mounting table. The rotary driving mechanism 121 rotatably drives the mounting table 102. The plurality of antenna units 140 are provided on the ceiling wall (upper wall) 111 of the processing container 101 facing the mounting table 102, and are not arranged axially symmetrically with respect to the rotation axis of the mounting table 102. Thereby, the plasma processing apparatus 100 according to an embodiment can make the plasma density on the substrate W uniform, even when the gap between the ceiling wall 111 and the mounting table 102 is shortened.

Further, the plurality of antenna units 140 are arranged such that the plasma density distribution in the radial direction of the mounting table 102 is within a predetermined range when each antenna unit generates plasma with a predetermined power. When the plasma processing is performed on the substrate W mounted on the mounting table 102, the controller 200 controls to rotatably drive the mounting table 102 by the rotary driving mechanism 121 and generate plasma with a predetermined power from the plurality of antenna units 140. Thereby, the plasma processing apparatus 100 according to an embodiment can keep the plasma density distribution in the radial direction of the mounting table 102 within a predetermined range even when the gap between the ceiling wall 111 and the mounting table 102 is shortened, thus making the plasma density on the substrate W uniform.

Further, the plurality of antenna units 140 are provided at different positions in the radial direction of the mounting table 102. Further, the plurality of antenna units 140 are arranged such that the arrangement density in the radial direction of the mounting table 102 increases toward the outside. Thereby, the plasma processing apparatus 100 according to an embodiment can make the plasma density in the radial direction of the mounting table 102 uniform.

Further, the plurality of antenna units 140 are arranged such that inner and outer antenna units 140 in the radial direction of the mounting table 102 appear alternately with respect to the rotation direction of the mounting table 102. Further, the plurality of antenna units 140 are arranged to be spaced apart from each other. Thereby, the plasma processing apparatus 100 according to an embodiment may secure a space around each antenna module 141, so that it is possible to suppress deterioration of handling wiring or the like, or interference with other members. In addition, interference of electromagnetic waves introduced from each antenna module in the processing container 101 can be suppressed.

Moreover, the plurality of antenna units 140 are not arranged at a position corresponding to the rotation axis of the mounting table 102 of the ceiling wall 111. Further, the introduction part 150 for introducing the remote plasma is provided at the position corresponding to the rotation axis of the mounting table 102 of the ceiling wall 111. Thereby, the plasma processing apparatus 100 according to an embodiment may introduce the plasma-activated cleaning gas by the remote plasma from near the center of the ceiling wall 111 into the processing container 101, thus allowing the inside of the processing container 101 to be uniformly cleaned.

The number of the plurality of antenna units 140 is seven or less. Even when the number of antenna units 140 is seven or less (e.g., four), the plasma processing apparatus 100 according to an embodiment may secure the uniformity of the plasma density on the substrate W.

Further, the processing container 101 is provided with the shower head for ejecting gas on the ceiling wall 111 where the plurality of antenna units 140 are not arranged. Thereby, the plasma processing apparatus 100 according to an embodiment can supply gas from the upper surface to the entire substrate W.

Although an embodiment has been described above, it should be contemplated that the embodiment is merely illustrative but is not restrictive. Various changes may be made on the above-described embodiment. In addition, the above-mentioned embodiment may be omitted, substituted, or changed in various forms without departing from the scope of the claims.

In the above embodiment, the case where the substrate W is a semiconductor wafer has been described as an example, but the present disclosure is not limited thereto. Any substrate W may be used.

Further, in the above embodiment, the case where the plasma source is the antenna module 141 that uses microwaves to generate plasma has been described as an example, but the present disclosure is not limited thereto. Any plasma source may be used as long as it may generate plasma.

Further, in the above embodiment, the case where the plasma processing apparatus is an apparatus for generating plasma using microwaves has been described as an example, but the present disclosure is not limited thereto. Any plasma processing apparatus may be used as long as it may generate plasma using a plurality of plasma sources.

Further, it should be contemplated that the foregoing embodiment is merely illustrative but is not restrictive. In practice, the above embodiment may be implemented in various forms. The above embodiment may be omitted, substituted, or changed in various forms without departing from the scope of the appended claims.

Regarding the above embodiment, the following appendices are disclosed.

### APPENDIX 1

A plasma processing apparatus comprising:
a stage disposed in a processing container and configured to mount thereon a substrate;
a rotary driving mechanism configured to rotatably drive the stage; and
a plurality of plasma sources provided on an upper wall of the processing container facing the stage, the plurality of plasma sources being not arranged axially symmetrically with respect to a rotation axis of the stage.

### APPENDIX 2

The plasma processing apparatus of appendix 1, wherein the plurality of plasma sources are arranged such that plasma density distribution in a radial direction of the stage is within a predetermined range when each plasma source generates plasma with a predetermined power, and
when plasma processing is performed on the substrate mounted on the stage, the apparatus further comprises a controller configured to control generation of plasma from the plurality of plasma sources, each with the predetermined power, while rotatably driving the stage by the rotary driving mechanism.

### APPENDIX 3

The plasma processing apparatus of appendix 1 or appendix 2, wherein the plurality of plasma sources are provided at different positions in a radial direction of the stage.

### APPENDIX 4

The plasma processing apparatus of any one of appendices 1 to 3, wherein the plurality of plasma sources are arranged such that inner and outer plasma sources in a radial direction of the stage appear alternately with respect to a rotation direction of the stage.

### APPENDIX 5

The plasma processing apparatus of any one of appendices 1 to 4, wherein the plurality of plasma sources are arranged such that an arrangement density thereof in a radial direction of the stage increases toward an outside.

### APPENDIX 6

The plasma processing apparatus of any one of appendices 1 to 5, wherein the plurality of plasma sources are arranged to be spaced apart from each other.

### APPENDIX 7

The plasma processing apparatus of any one of appendices 1 to 6, wherein the plurality of plasma sources are not arranged at a position corresponding to the rotation axis of the stage of the upper wall.

### APPENDIX 8

The plasma processing apparatus of appendix 7, wherein an introduction part for introducing remote plasma is provided at the position corresponding to the rotation axis of the stage of the upper wall.

### APPENDIX 9

The plasma processing apparatus of any one of appendices 1 to 8, wherein a number of the plurality of plasma sources is seven or less.

### APPENDIX 10

The plasma processing apparatus of any one of appendices 1 to 9, wherein the processing container is provided with a shower head for ejecting gas on the upper wall where the plurality of antenna units are not arranged.

### APPENDIX 11

A plasma processing method comprising:
rotatably driving a stage disposed in a processing container and configured to mount thereon a substrate; and
generating plasma using a plurality of plasma sources that are provided on an upper wall of the processing container facing the stage and are not arranged axially symmetrically with respect to a rotation axis of the stage.

1. A plasma processing apparatus comprising:
a stage disposed in a processing container and configured to mount thereon a substrate;
a rotary driving mechanism configured to rotatably drive the stage; and
a plurality of plasma sources provided on an upper wall of the processing container facing the stage, the plurality of plasma sources being not arranged axially symmetrically with respect to a rotation axis of the stage.

2. The plasma processing apparatus of claim 1, wherein the plurality of plasma sources are arranged such that plasma density distribution in a radial direction of the stage is within a predetermined range when each plasma source generates plasma with a predetermined power, and
when plasma processing is performed on the substrate mounted on the stage, the apparatus further comprises a controller configured to control generation of plasma from the plurality of plasma sources, each with the predetermined power, while rotatably driving the stage by the rotary driving mechanism.

3. The plasma processing apparatus of claim 1, wherein the plurality of plasma sources are provided at different positions in a radial direction of the stage.

4. The plasma processing apparatus of claim 1, wherein the plurality of plasma sources are arranged such that inner and outer plasma sources in a radial direction of the stage appear alternately with respect to a rotation direction of the stage.

5. The plasma processing apparatus of claim 1, wherein the plurality of plasma sources are arranged such that an arrangement density thereof in a radial direction of the stage increases toward an outside.

6. The plasma processing apparatus of claim 1, wherein the plurality of plasma sources are arranged to be spaced apart from each other.

7. The plasma processing apparatus of claim 1, wherein the plurality of plasma sources are not arranged at a position corresponding to the rotation axis of the stage of the upper wall.

8. The plasma processing apparatus of claim 7, wherein an introduction part for introducing remote plasma is provided at the position corresponding to the rotation axis of the stage of the upper wall.

9. The plasma processing apparatus of claim 1, wherein a number of the plurality of plasma sources is seven or less.

10. The plasma processing apparatus of claim 1, wherein the processing container is provided with a shower head for ejecting gas on the upper wall where the plurality of antenna units are not arranged.

11. A plasma processing method comprising:
rotatably driving a stage disposed in a processing container and configured to mount thereon a substrate; and
generating plasma using a plurality of plasma sources that are provided on an upper wall of the processing container facing the stage and are not arranged axially symmetrically with respect to a rotation axis of the stage.
